(19) United States
(12) Patent Application Publication
(10) Pub. No.: US 2024/0167809 A1
(43) Pub. Date: May 23, 2024

(54) METROLOGY SYSTEMS, MEASUREMENT OF WEAR SYSTEMS AND METHODS THEREOF

(71) Applicant: ASML Holding N.V., Veldhoven (NL)

(72) Inventors: Venkata Siva Chaithanya CHILLARA, Norwalk, CT (US); Kellen SANNA, Norwalk, CT (US)

(73) Assignee: ASML Holding N.V., Veldhoven (NL)

(21) Appl. No.: 18/284,019

(22) PCT Filed: Mar. 31, 2022
(86) PCT No.: PCT/EP2022/058670

§ 371 Date: Sep. 25, 2023

Related U.S. Application Data
(60) Provisional application No. 63/172,372, filed on Apr. 8, 2021.

(51) Int. Cl. G01B 11/06; G03F 7/00

(52) U.S. Cl. CPC G01B 11/0616; G03F 7/706839; G03F 7/707; G03F 7/7085

(57) ABSTRACT

A method includes irradiating an object with an illumination beam, receiving, using a detector, scattered light from a first side of the object, generating a signal based on the scattered light, comparing the signal to a reference model, and determining a quantity of wear of the first side of the object based on the comparing. The first side of the object includes a layer of a coating material, and the irradiating is from a second side of the object. The scattered light includes transmitted light through the object from the second side to the first side.

### CROSS-REFERENCE TO RELATED APPLICATIONS

This application claims priority of U.S. Provisional Patent Application No. 63/172,372, which was filed on Apr. 8, 2021, and which is incorporated herein in its entirety by reference.

### FIELD

The present disclosure relates to measurement of wear of a layer, for example, detection of wear in burls used in lithographic apparatuses.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

There is a continuing desire to manufacture devices, e.g. integrated circuits, with ever smaller features. Integrated circuits and other microscale devices are often manufactured using optical lithography, but other manufacturing techniques, such as imprint lithography, e-beam lithography and nano-scale self-assembly are known.

During manufacturing, a device (e.g., a patterning device) is irradiated. It is important to ensure that the irradiation process is as accurate as possible. One of the issues with making the irradiation processes as accurate as possible is ensuring that the device to be irradiated is in the correct position. In order to control the position of the device, a substrate holder can be used. Generally, a substrate can be supported by the substrate holder whilst the substrate is being irradiated. When the substrate is positioned on the substrate holder, friction between the substrate and the substrate holder can prevent the substrate from flattening out over a surface of the substrate holder. To address this issue, the substrate holder can be provided with support elements that minimize the contact area between the substrate and the substrate holder. The support elements on the surface of the substrate holder can otherwise be referred to as burls or protrusions. The support elements are generally regularly spaced (e.g. in a uniform array) and of uniform height and define a very flat overall support surface on which the substrate can be positioned. The support elements reduce the contact area between the substrate holder and the substrate, thus reducing friction, and allowing the substrate to move to a flatter position on the substrate holder.

Support elements and the substrate holder may be subject to wear due to the clamping and unclamping of the substrate or due to friction during the substrate movement. Support elements may be coated by a thin film. Structural integrity of the substrate holder may depend on the endurance of the thin film.

### SUMMARY

It is desirable to determine a quantity of wear of the support elements while minimizing interruptions in the operation of the lithographic apparatus.

In some embodiments, a method comprises irradiating an object with an illumination beam, receiving, using a detector, scattered light on the first side of the object, generating, using the detector, a signal based on the scattered light, comparing, using a processor, the signal to a reference model, determining, using the processor, a quantity of wear of the first side of the object based on the comparing. The first side of the object comprises a layer of a coating material and the irradiating is from a second side of the object. The scattered light includes transmitted light through the object from the second side to the first side.

In some embodiments, a system comprises an illumination system, a detection system, and processing circuitry. The illumination system is configured to generate an illumination beam and to direct the illumination beam to irradiate a second side of an object. A first side of the object comprises a layer of a coating material. The detection system is configured to receive scattered light on the first side of the object. The processing circuitry is configured to generate a signal based on the received light, compare the signal to a reference model, and determine a quantity of wear of the first side of the object based on the comparing. The scattered light includes transmitted light through the object from the second side to the first side.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1A illustrates a reflective lithographic apparatus, according to some embodiments.

FIG. 1B illustrates a transmissive lithographic apparatus, according to some embodiments.

FIG. 2 illustrates a more detailed schematic of the reflective lithographic apparatus, according to some embodiments.

FIG. 3 illustrates a schematic of a lithographic cell, according to some embodiments.

FIG. 4 illustrates a wear measurement system, according to some embodiments.

FIGS. 5A and 5B illustrate a reference sample, according to some embodiments.

FIGS. 6A and 6B illustrate transmission and reflection spectra of a Titanium (Ti) layer, according to some embodiments.

FIG. 7 illustrates transmission spectra of Titanium Nitride (TiN) coated substrates, according to some embodiments.

FIGS. 8A and 8B illustrate optical density spectra, according to some embodiments.

FIG. 9 illustrates transmission of TiN coated substrates and a Ti adhesion layer as a function of thickness, according to some embodiments.

FIGS. 10A and 10B illustrate the reflectivity and transmission spectra for titanium layers of various thicknesses, according to some embodiments.

FIG. 11 illustrates the transmission spectra of a Titanium (Ti) layer as a function of the thickness of the layer, according to some embodiments.

FIG. 12 illustrates a processed image of a clamping interface, according to some embodiments.

FIG. 13 illustrates a histogram for pixel intensities, according to some embodiments.

FIG. 14 illustrates a worn area ratio as a function of slip-scans, according to some embodiments.

FIG. 15 illustrates method steps for performing a method including functions described herein, according to some embodiments.

FIG. 16 illustrates a block diagram of a computer system, according to some embodiments.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” may indicate a value of a given quantity that varies within, for example, 10-30% of the value (e.g., ±10%, ±20%, or ±30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure can be implemented.

### Example Lithographic Systems

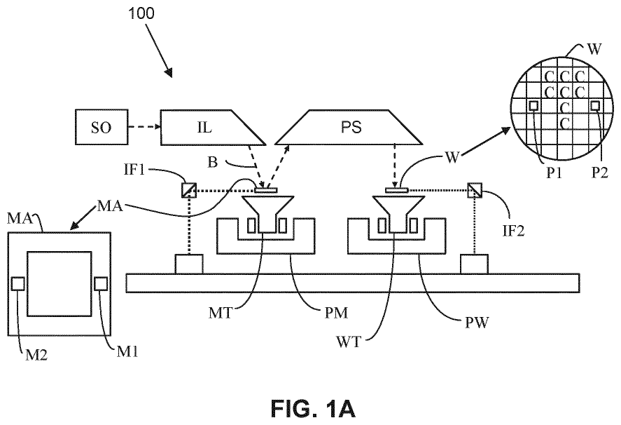

FIGS. 1A and 1B show schematic illustrations of a lithographic apparatus 100 and lithographic apparatus 100′, respectively, in which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT may be a frame or a table, for example, which may be fixed or movable, as required. By using sensors, the support structure MT may ensure that the patterning device MA is at a desired position, for example, with respect to the projection system PS.

The term “patterning device” MA should be broadly interpreted as referring to any device that may be used to impart a radiation beam B with a pattern in its cross-section, such as to create a pattern in the target portion C of the substrate W. The pattern imparted to the radiation beam B may correspond to a particular functional layer in a device being created in the target portion C to form an integrated circuit.

The terms “inspection apparatus,” “metrology apparatus,” and the like may be used herein to refer to, e.g., a device or system used for measuring a property of a structure (e.g., overlay error, critical dimension parameters) or used in a lithographic apparatus to inspect an alignment of a wafer (e.g., alignment apparatus).

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which may be individually tilted so as to reflect an incoming radiation beam in different directions. The tilted mirrors impart a pattern in the radiation beam B, which is reflected by a matrix of small mirrors.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment may be used for EUV or electron beam radiation since other gases may absorb too much radiation or electrons. A vacuum environment may therefore be provided to the whole beam path with the aid of a vacuum wall and vacuum pumps.

Lithographic apparatus 100 and/or lithographic apparatus 100′ may be of a type having two (dual stage) or more substrate tables WT (and/or two or more mask tables). In such “multiple stage” machines, the additional substrate tables WT may be used in parallel, or preparatory steps may be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ may be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO may be an integral part of the lithographic apparatus 100, 100′, for example, when the source SO is a mercury lamp. The source SO and the illuminator IL, together with the beam delivery system BD, if required, may be referred to as a radiation system.

The illuminator IL may include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator may be adjusted. In addition, the illuminator IL may comprise various other components (in FIG. 1B), such as an integrator IN and a condenser CO. The illuminator IL may be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT may be moved accurately (for example, so as to position different target portions C in the path of the radiation beam B). Similarly, the first positioner PM and another position sensor IF1 may be used to accurately position the patterning device (for example, mask) MA with respect to the path of the radiation beam B. Patterning device (for example, mask) MA and substrate W may be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image MP′ of the mask pattern MP, where image MP′ is formed by diffracted beams produced from the mark pattern MP by radiation from the intensity distribution, onto a photoresist layer coated on the substrate W. For example, the mask pattern MP may include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line may be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration may be reduced by providing radiation poles (not shown) in opposite quadrants of the illumination system pupil IPU. Further, in some embodiments, astigmatism aberration may be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IF (for example, an interferometric device, linear encoder, or capacitive sensor), the substrate table WT may be moved accurately (for example, so as to position different target portions C in the path of the radiation beam B). Similarly, the first positioner PM and another position sensor (not shown in FIG. 1B) may be used to accurately position the mask MA with respect to the path of the radiation beam B (for example, after mechanical retrieval from a mask library or during a scan).

In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the mask table MT may be connected to a short-stroke actuator only or may be fixed. Mask MA and substrate W may be aligned using mask alignment marks M1, M2, and substrate alignment marks P1, P2. Although the substrate alignment marks (as illustrated) occupy dedicated target portions, they may be located in spaces between target portions (known as scribe-lane alignment marks). Similarly, in situations in which more than one die is provided on the mask MA, the mask alignment marks may be located between the dies.

Mask table MT and patterning device MA may be in a vacuum chamber V, where an in-vacuum robot IVR may be used to move patterning devices such as a mask in and out of vacuum chamber. Alternatively, when mask table MT and patterning device MA are outside of the vacuum chamber, an out-of-vacuum robot may be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ may be used in at least one of the following modes:

1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C may be exposed.

2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT may be determined by the (de-)magnification and image reversal characteristics of the projection system PS.

3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO may be employed and the programmable patterning device is updated as required after each movement of the substrate table WT or in between successive radiation pulses during a scan. This mode of operation may be readily applied to maskless lithography that utilizes a programmable patterning device, such as a programmable mirror array.

Combinations and/or variations on the described modes of use or entirely different modes of use may also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

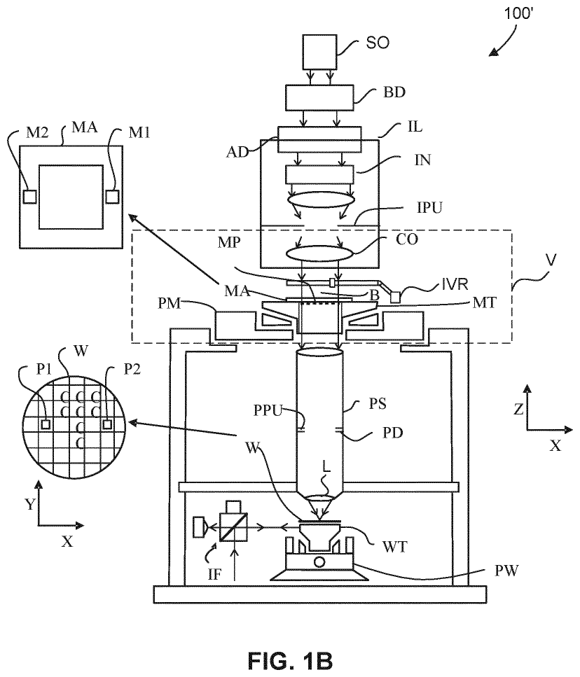

FIG. 2 shows the lithographic apparatus 100 in more detail, including the source collector apparatus SO, the illumination system IL, and the projection system PS. The source collector apparatus SO is constructed and arranged such that a vacuum environment may be maintained in an enclosing structure 220 of the source collector apparatus SO. An EUV radiation emitting plasma 210 may be formed by a discharge produced plasma source. EUV radiation may be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure.

The collector chamber 212 may include a radiation collector CO, which may be a so-called grazing incidence collector. Radiation collector CO has an upstream radiation collector side 251 and a downstream radiation collector side 252. Radiation that traverses collector CO may be reflected off a grating spectral filter 240 to be focused in a virtual source point IF. The virtual source point IF is commonly referred to as the intermediate focus, and the source collector apparatus is arranged such that the intermediate focus IF is located at or near an opening 219 in the enclosing structure 220. The virtual source point IF is an image of the radiation emitting plasma 210. Grating spectral filter 240 is used in particular for suppressing infra-red (IR) radiation.

Subsequently the radiation traverses the illumination system IL, which may include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the FIG. 2, for example there may be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Exemplary Lithographic Cell

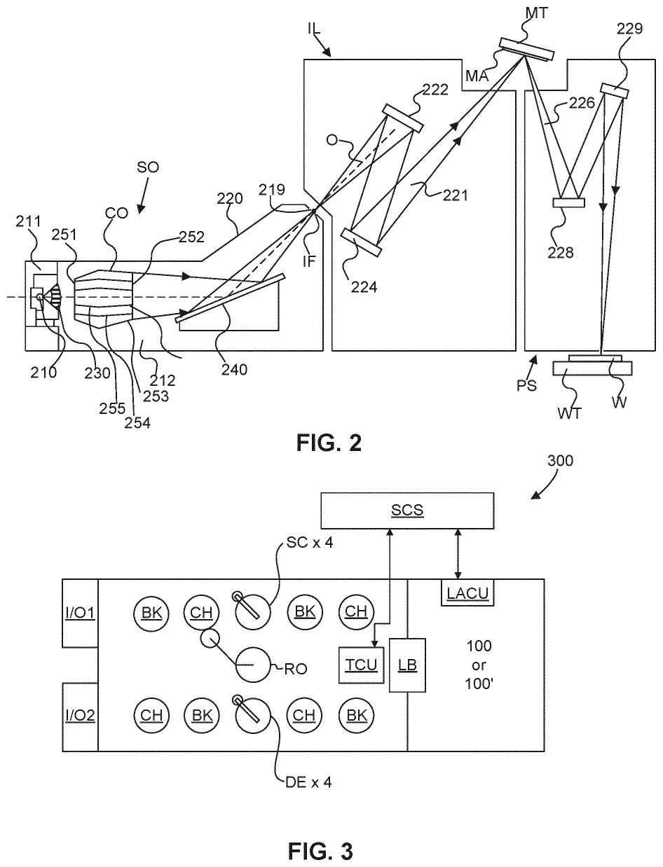

FIG. 3 shows a lithographic cell 300, also sometimes referred to a lithocell or cluster, according to some embodiments. Lithographic apparatus 100 or 100′ may form part of lithographic cell 300. Lithographic cell 300 may also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses may be operated to maximize throughput and processing efficiency.

In some embodiments, clamping interfaces (i.e., burls) may include a thin film coating. The thin film coating or wear resistant layer may protect the clamping interfaces against wear. In some aspects, the clamping interfaces may be subject to wear due to clamping/unclamping of the reticle and/or due to static friction during scanning. In some aspects, the thin film endurance is a factor in the structural integrity of the clamping interface.

In some embodiments, white light interferometry (WLI), atomic force microscopy (AFM), scanning electron microscopy (SEM), time of flight secondary ion mass spectroscopy (TOF-SIMS), and profilometry techniques may be used to measure wear in thin films. In some aspects, these techniques suffer from a variety of disadvantages. For example, WLI is sensitive to changes in coating's optical parameters. AFM may not provide a sufficient field of view to cover an entire clamping interface. SEM does not accurately determine wear depth. TOF-SIMS is time consuming Profilometry techniques do not provide a desired resolution.

Embodiments of the present disclosure provide functions to more quickly and efficiently perform inspection of a thin-film coating on a substrate. Embodiments of the present disclosure provide functions to quantify mechanical wear in opaque thin films coated on a transparent substrate by measuring light transmitted through the film and substrates. The method described herein may be used to qualify coating quality on clamping interfaces (e.g., reticle clamps). In some embodiments, the clamping interface may comprise a plurality of burls formed on a plate (e.g., a glass substrate). The method described herein may be used to qualify coating after production and to measure wear on reticle clamps or burls in the field (in-situ detection of wear).

In some aspects, the plurality of burls may be coated using a wear resistant layer (e.g., Titanium Nitride (TiN)). In some aspects, a relation between light transmittance through the plate and a coating thickness is determined. In some aspects, the relation may be a function of optical constants of the material forming the wear resistant layer and/or other layers on the clamping interface. In some aspects, optical constants of Titanium Nitride (TiN) thin films are determined using spectrophotometry.

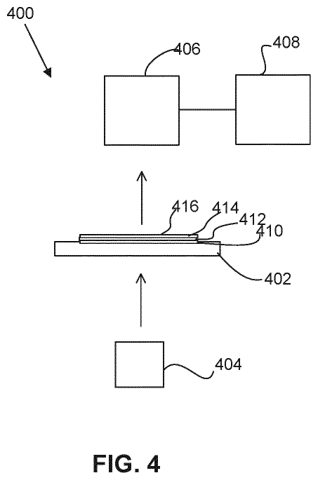

FIG. 4 illustrates a wear measurement system 400 for determining a quantity of wear of a surface of a clamping interface, according to some embodiments. In some embodiments, system 400 comprises an illumination system 404, a detector 406, and a processor 408. In some embodiments, a clamping interface 402 may be illuminated from a first side using radiation (light) of a known wavelength.

In some embodiments, clamping interface 402 can include a plurality of burls 410 on a second side. In some embodiments, detector 406 can capture one or more images of clamping interface 402 from the second side (e.g., above) under fixed ambient lighting conditions. In some embodiments, detector 406 can comprise a camera (e.g., CCD camera). The camera can be used to acquire one or more images of clamping interface 402.

In some embodiments, the plurality of burls 410 may comprise a wear resistant layer 414 and an adhesion layer 412. In some aspects, adhesion layer 412 is formed on a surface of the plurality of burls 410 before the wear resistant layer 414 is formed.

In some aspects, detector 406 can output a signal to processor 408. In some aspects, processor 408 is configured to determine an intensity of light passing through the clamping interface 402 or scattered at a surface 416 of the clamping interface 402. In some aspects, the intensity of light may be indicative of the quantity of wear. In some embodiments, processor 408 can be configured to determine a percentage of remaining coating of the wear resistant layer 414 and/or the adhesion layer 412 based on the signal. For example, a percentage of remaining coating of the wear resistant layer 414 and/or the adhesion layer 412 may be determined based on the intensity of light.

In some embodiments, the quantity of wear may be determined using a reference model. The reference model may be stored in processor 408, a database or a memory (not shown) associated with processor 408, or the like. The reference model may be established before inspecting the clamping interface 402 as described later herein.

In some embodiments, the reference model is established by identifying optical constants associated with materials of the wear resistant layer 414 and the adhesion layer 412 of the clamping interface 402. In some aspects, the optical constants of the coating layer may be measured using spectrophotometry. In some embodiments, the wear resistant layer 414 may be formed using TiN.

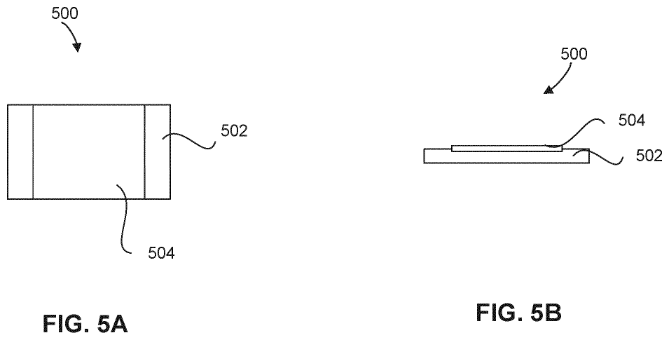

FIGS. 5A and 5B show top and side views, respectively, of a sample 500, according to some embodiments. In some embodiments, optical constants of TiN are measured using spectrophotometry. For example, samples can be prepared by coating a blank substrate 502 with a TiN layer 504. Spectrophotometry measurements can be conducted on samples having a plurality of thickness. The thickness of the coating may vary for each sample, e.g., 10 nm, 20 nm, 30 nm. In some aspects, sample 500 can include an adhesion layer (e.g., Ti layer) (not shown). In some aspects, a thickness of the adhesion layer is the same as used in the production of clamping interfaces 402.

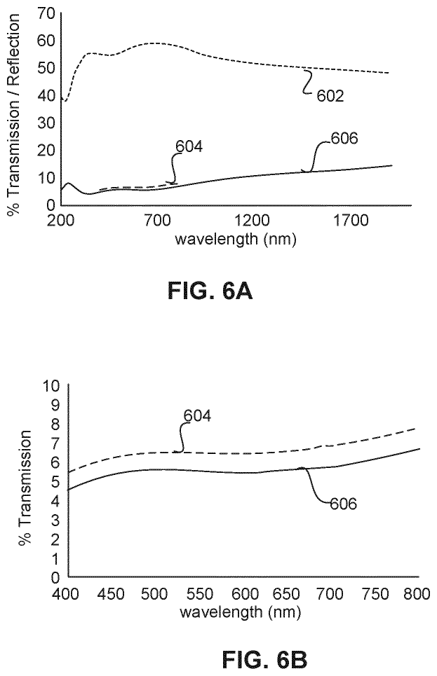

FIG. 6A illustrates reflection and transmission spectra of a titanium (Ti) layer, according to some embodiments. A blown-up view of transmission curve 604 and transmission curve 606 in the visible region is shown in FIG. 6B.

In one aspect, reflection curve 602 shows the modelled reflection for a titanium layer having a thickness of 30 nm. In one aspects, transmission curve 604 shows the measured transmission over the visible region for the titanium layer. In one aspect, transmission curve 606 shows the modelled transmission for the titanium layer. In some embodiments, reflection curve 602 and transmission curve 606 are determined using literature values of n and k for titanium (Ti).

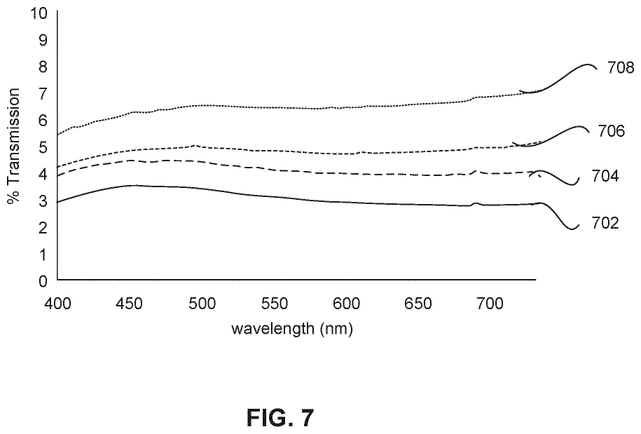

FIG. 7 illustrates transmission spectra of TiN coated substrates, according to some embodiments. In one aspect, transmission curve 708 is for a non-coated substrate. For example, transmission curve 706 can be for a substrate having a 10 nm TiN layer. In one example, transmission curve 704 is for a substrate having a 20 nm TiN layer. In one example, transmission curve 702 is for a substrate having a 30 nm TiN layer. In some embodiments, transmission decreases with an increase in the thickness of the TiN layer. However, in other embodiments the decrease in the transmission may not be proportional to the increase in the thickness.

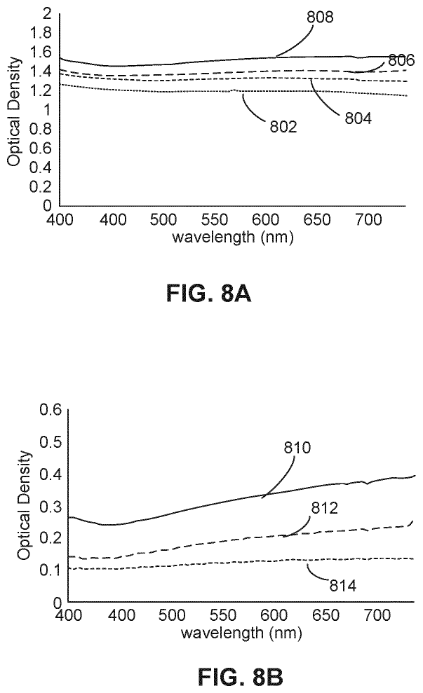

In some embodiments, an optical density (OD) of TiN coated substrates may be determined based on a transmission spectra. For example, optical densities corresponding to the transmission spectra shown in FIG. 7 are shown in FIG. 8A, according to some embodiments. In one aspect, optical density curve 802 is for a non-coated substrate. In one example, optical density curve 804 is for a substrate having a 10 nm TiN layer. In one example, optical density curve 804 is for a substrate having a 20 nm TiN layer. In one example, optical density curve 808 is for a substrate having a 30 nm TiN layer. In some aspects, optical density may increase linearly with a thickness of the coating layer (e.g., layer of TiN 504 of FIG. 5A).

In some embodiments, the optical OD associated with the Ti layer may be subtracted from the OD associated with the coated samples. Optical density with the OD of Ti subtracted are shown in FIG. 8B according to some embodiments. In one example, optical density curve 810 is for a substrate having a 30 nm TiN layer. In one example, optical density curve 812 is for a substrate having a 20 nm TiN layer. Optical density curve 814 is for a substrate having a 10 nm TiN layer.

In some embodiments, an average optical density of a desired region of the spectrum may be determined. For example, an average optical density over the visible region may be determined. In some embodiments, an extinction factor for the wear resistant layer or TiN film thickness may be determined. For example, the average OD of 30 nm Ti in the visible region (i.e., 450 nm to 700 nm) may be about 1.2. The average extinction may be about 0.02.

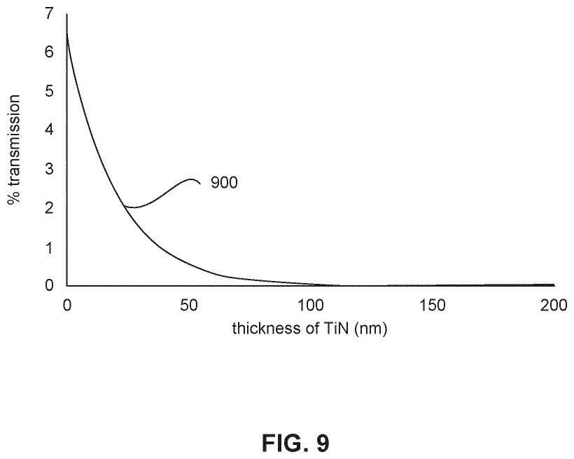

Transmission curve 900 in FIG. 9 shows the transmission as a function of the thickness of a TiN layer, according to some embodiments. In one example, the TiN layer is deposited on a 30 nm layer of Ti on a glass substrate. In some embodiments, the transmission is integrated in the visible region (i.e., 450 nm to 700 nm). In some embodiments, the transmission may be expressed as T=100×10^{-(OD×extinction×t)} wherein OD is the average optical density of the adhesive layer or Ti and t is the thickness of the coating (e.g., TiN layer).

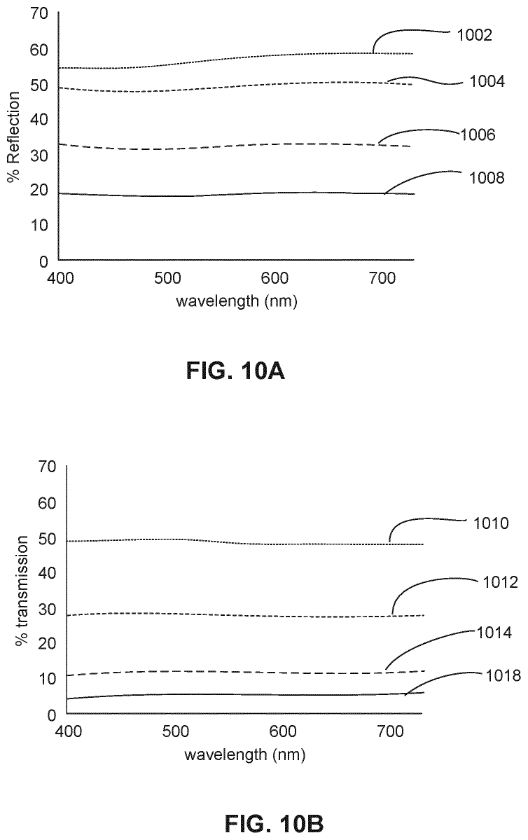

FIGS. 10A and 10B illustrate the reflectivity and transmission spectra for titanium layers of various thicknesses, in accordance with some embodiments. In one example, reflection curve 1002 is for a 30 nm Ti layer. In one example, reflection curve 1004 is for a 20 nm Ti layer. In one example, reflection curve 1006 is for a 10 nm Ti layer. In one example, reflection curve 1008 is for a 5 nm Ti layer. In one example, transmission curve 1010 is for a 5 nm Ti layer. In one example, transmission curve 1012 is for a 10 nm Ti layer. In one example, transmission curve 1014 is for a 20 nm Ti layer. In one example, transmission curve 1018 is for a 30 nm Ti layer. As shown in FIG. 10B, the transmission increases rapidly as the thickness decreases.

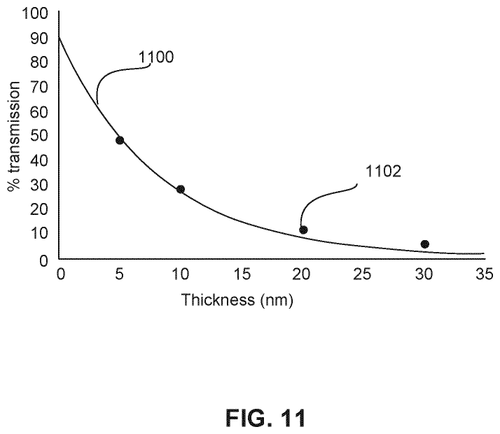

FIG. 11 illustrates the transmission spectra of a titanium (Ti) layer as a function of the thickness (nm) of the layer, according to some embodiments. In some embodiments, the transmission may be modelled as: T=90×e^{-(0.12×t)} where t is the thickness of Ti layer in nm and 0.12 is the extinction factor for Ti (i.e., base 10/nm of Ti averaged in the visible range 450 nm to 700 nm). Transmission curve 1100 shows the modelled transmission. Data points 1102 may correspond to the measured transmission. The transmission can be integrated in the visible region (i.e., 450 nm to 700 nm).

In some embodiments, the reference models (i.e., curve 900 of FIG. 9) previously described may be used to measure the wear on a clamping interface. Although the reference model described herein was in reference to a TiN layer, it is understood that reference models for other materials can be established.

In some embodiments, an image including one or more burls is acquired, for example, using detector 406 of FIG. 4. In some aspects, the image may be manipulated (e.g., cropped). The image may be converted to grayscale for further processing.

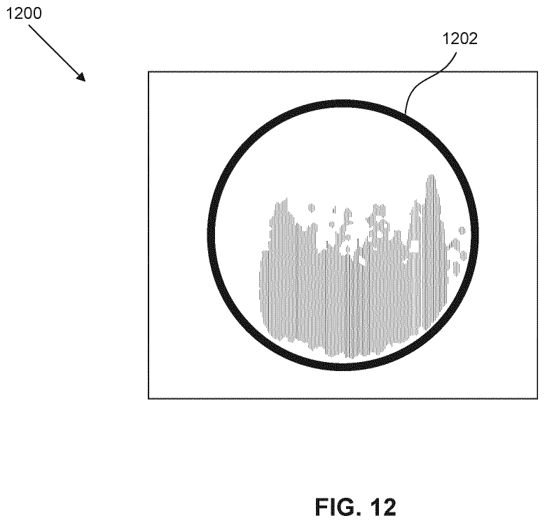

FIG. 12 illustrates a processed image 1200 of a burl, according to some embodiments. In some embodiments, a burl area 1202 can be defined. In some embodiments, the intensity of all the pixels in the defined area may be calculated.

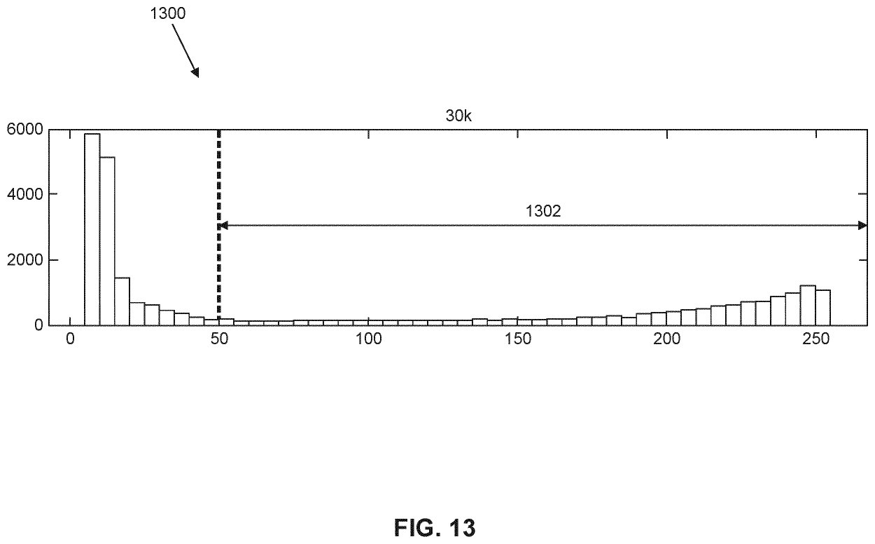

In some aspects, the intensities may be grouped using a histogram. In some aspects, pixels from all the burls on the clamping interface are included in the histogram. FIG. 13 illustrates a histogram 1300, according to some embodiments. Visible (bright) pixels 1302 may be identified. The burls may not be visible below a threshold intensity (division between and non-visible is shown as a dashed line in FIG. 13).

$$Area Ratio = \frac{Intensity of bright pixels}{Intensity of all pixels} .$$

In some aspects, a wear area ratio may be expressed as:

In some embodiments, the wear area ratio may be compared to an intensity of a reference clamping interface stored in the reference model.

In some embodiments, a critical coating thickness may be determined. In some aspects, the critical coating thickness may correspond to the minimum thickness or the transmitted backlight to be visible.

$$Volume Ratio = \frac{Intensity of bright pixels}{Intensity of all pixels} \times \frac{Remaining coating height}{Inital coating height} .$$

In some embodiments, a wear volume ration may be expressed as:

In some embodiments, the remaining coating height is determined based on the reference model established using the optical constants of the material (e.g., TiN and Ti). The optical constants may be determined using spectrophotometry measurements as described previously herein. For example, transmission curve 900 may be used to determine the remaining thickness of TiN based on the intensity of the detected light.

In some embodiments, the wear volume ratio is calculated when there is a layer-by-layer material removal. In some embodiments, the wear area ratio can be calculated for offline tests. In some aspects, wear may be initiated by the formation of scratches on the wear resistant layer.

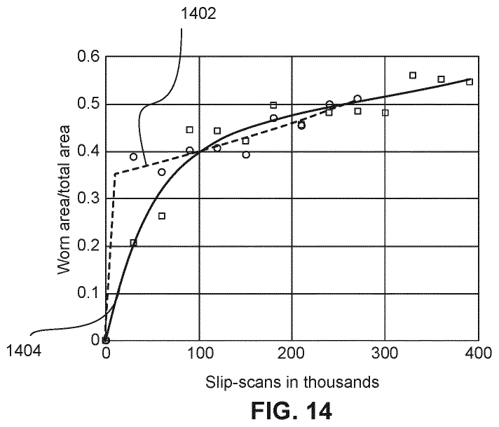

FIG. 14 illustrates a worn area ratio as a function of slip-scans (in thousands). In one example, curve 1402 illustrates the worn area ratio (i.e., worn area/total area) for a 150 nm TiN layer. In one example, curve 1404 illustrates the worn area ratio for a 300 nm TiN layer. In one example, curve 1402 and curve 1404 may be generated by fitting measured data point to a two-term exponential function.

In some aspects, the processor may be a processor of a lithography apparatus and the testing is done without removing the clamping interface from the lithography apparatus. The measurement may be done simultaneously with other measurements such as using a reticle clamp inspection tool.

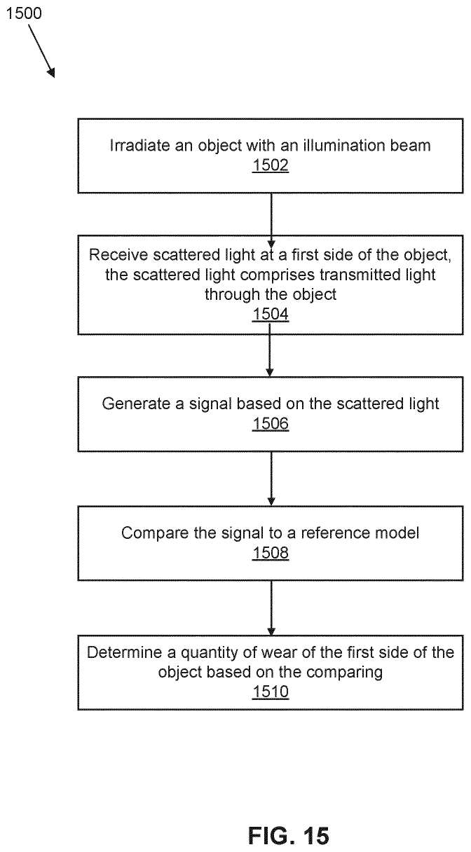

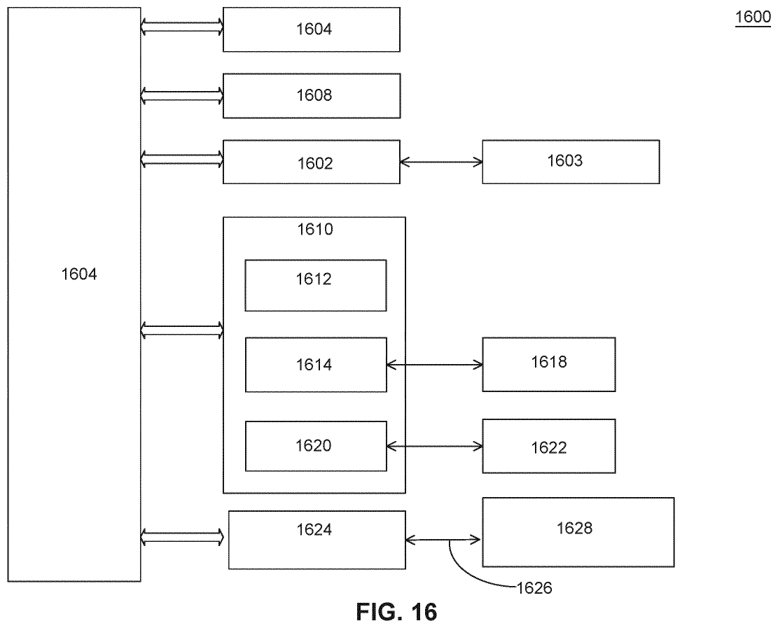

FIG. 15 illustrates an example method 1500 for determining a quantity of wear, according to some embodiments of the disclosure. Method 1500 may represent the operation of a system (e.g., system 400) implementing operations for determining a quantity of wear of a surface. Method 1500 may also be performed by computer system 1600 of FIG. 16. But, method 1500 is not limited to the specific embodiments depicted in those figures, and other systems may be used to perform the method as will be understood by those skilled in the art. It is to be appreciated that not all operations may be needed, and the operations may not be performed in the same order as shown in FIG. 15.

At 1502, an object is irradiated with an illumination beam. The object can include a first side and a second side. In some aspects, the first side of the object may include a coating layer. For example, the first side of the object can comprise burls coated with a wear resistant layer. In some aspects, the object is illuminated from the second side.

At 1504, scattered light at the first side of the object may be received by a detector. The scattered light may include transmitted light through the object from the second side to the first side. For example, one or more images of the first side of the object may be captured using a camera.

At 1506, a signal based on the scattered light may be generated by the detector. For example, image data associated with the captured one or more images may be generated.

At 1508, the signal may be compared to a reference model. For example, an intensity of the signal may be compared to the reference model. In some aspects, the reference model associated with the material of the coating layer may be retrieved from a memory.

At 1510, a quantity of wear of the first side of the object based on the comparing. For example, the thickness of the coating layer may be determined by comparing the intensity of the signal with predetermined intensity and thicknesses stored in the reference model. In some aspects, an average intensity of pixels in the captured images may be compared with a reference intensity stored in the reference model.

In some embodiments, the quantity of wear is communicated to a processor of the lithography apparatus (e.g., lithography apparatus 100 of FIG. 1A). In some aspects, a warning may be issued in the lithography apparatus when the intensity of the signal is greater than a threshold.

Various embodiments may be implemented, for example, using one or more well-known computer systems, such as computer system 1600 shown in FIG. 16. One or more computer systems 1600 may be used, for example, to implement any aspect of the disclosure discussed herein, as well as combinations and sub-combinations thereof.

Computer system 1600 may include one or more processors (also called central processing units, or CPUs), such as a processor 1604. Processor 1604 may be connected to a communication infrastructure or bus 1606.

Computer system 1600 may also include customer input/output device(s) 1603, such as monitors, keyboards, pointing devices, etc., which may communicate with communication infrastructure 1606 through customer input/output interface(s) 1602.

One or more of processors 1604 may be a graphics processing unit (GPU). In an embodiment, a GPU may be a processor that is a specialized electronic circuit designed to process mathematically intensive applications. The GPU may have a parallel structure that is efficient for parallel processing of large blocks of data, such as mathematically intensive data common to computer graphics applications, images, videos, etc.

Computer system 1600 may also include a main or primary memory 1608, such as random access memory (RAM). Main memory 1608 may include one or more levels of cache. Main memory 1608 may have stored therein control logic (i.e., computer software) and/or data.

Computer system 1600 may also include one or more secondary storage devices or memory 1610. Secondary memory 1610 may include, for example, a hard disk drive 1612 and/or a removable storage device or drive 1614. Removable storage drive 1614 may be a floppy disk drive, a magnetic tape drive, a compact disk drive, an optical storage device, tape backup device, and/or any other storage device/drive. In some embodiments, the reference model can stored in storage device 1610 accessible by processor 1604.

Removable storage drive 1614 may interact with a removable storage unit 1618. Removable storage unit 1618 may include a computer usable or readable storage device having stored thereon computer software (control logic) and/or data. Removable storage unit 1618 may be a floppy disk, magnetic tape, compact disk, DVD, optical storage disk, and/any other computer data storage device. Removable storage drive 1614 may read from and/or write to removable storage unit 1618.

Secondary memory 1610 may include other means, devices, components, instrumentalities or other approaches for allowing computer programs and/or other instructions and/or data to be accessed by computer system 1600. Such means, devices, components, instrumentalities or other approaches may include, for example, a removable storage unit 1622 and an interface 1620. Examples of the removable storage unit 1622 and the interface 1620 may include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Computer system 1600 may further include a communication or network interface 1624. Communication interface 1624 may enable computer system 1600 to communicate and interact with any combination of external devices, external networks, external entities, etc. (individually and collectively referenced by reference number 1628). For example, communication interface 1624 may allow computer system 1600 to communicate with external or remote devices 1628 over communications path 1626, which may be wired and/or wireless (or a combination thereof), and which may include any combination of LANs, WANs, the Internet, etc. Control logic and/or data may be transmitted to and from computer system 1600 via communication path 1626.

Computer system 1600 may also be any of a personal digital assistant (PDA), desktop workstation, laptop or notebook computer, netbook, tablet, smart phone, smart watch or other wearable, appliance, part of the Internet-of-Things, and/or embedded system, to name a few non-limiting examples, or any combination thereof.

Computer system 1600 may be a client or server, accessing or hosting any applications and/or data through any delivery paradigm, including but not limited to remote or distributed cloud computing solutions; local or on-premises software (“on-premise” cloud-based solutions); “as a service” models (e.g., content as a service (CaaS), digital content as a service (DCaaS), software as a service (SaaS), managed software as a service (MSaaS), platform as a service (PaaS), desktop as a service (DaaS), framework as a service (FaaS), backend as a service (BaaS), mobile backend as a service (MBaaS), infrastructure as a service (IaaS), etc.); and/or a hybrid model including any combination of the foregoing examples or other services or delivery paradigms.

Any applicable data structures, file formats, and schemas in computer system 1600 may be derived from standards including but not limited to JavaScript Object Notation (JSON), Extensible Markup Language (XML), Yet Another Markup Language (YAML), Extensible Hypertext Markup Language (XHTML), Wireless Markup Language (WML), MessagePack, XML User Interface Language (XUL), or any other functionally similar representations alone or in combination. Alternatively, proprietary data structures, formats or schemas may be used, either exclusively or in combination with known or open standards.

In some embodiments, a tangible, non-transitory apparatus or article of manufacture comprising a tangible, non-transitory computer useable or readable medium having control logic (software) stored thereon may also be referred to herein as a computer program product or program storage device. This includes, but is not limited to, computer system 1600, main memory 1608, secondary memory 1610, and removable storage units 1618 and 1622, as well as tangible articles of manufacture embodying any combination of the foregoing. Such control logic, when executed by one or more data processing devices (such as computer system 1600), may cause such data processing devices to operate as described herein.

Based on the teachings contained in this disclosure, it will be apparent to persons skilled in the relevant art(s) how to make and use embodiments of this disclosure using data processing devices, computer systems and/or computer architectures other than that shown in FIG. 16. In particular, embodiments can operate with software, hardware, and/or operating system implementations other than those described herein.

The term “substrate” as used herein describes a material onto which material layers are added. In some embodiments, the substrate itself can be patterned and materials added on top of it may also be patterned, or may remain without patterning

The embodiments may further be described using the following clauses:

1. A method comprising:
irradiating an object with an illumination beam, wherein:
   a first side of the object comprises a layer of a coating material, and
   the irradiating is from a second side of the object;
receiving, using a detector, scattered light from the first side of the object, wherein the scattered light comprises transmitted light through the object from the second side to the first side;
generating, using the detector, a signal based on the scattered light;
comparing, using a processor, the signal to a reference model; and
determining, using the processor, a quantity of wear of the first side of the object based on the comparing.

2. The method of clause 1, wherein:
the quantity of wear comprises a wear area ratio,
the signal comprises image data of the object, and
the wear area ratio is a function of an intensity of bright pixels in the image data.

3. The method of clause 2, wherein the analyzing further comprises:
defining an area of interest based on the image data; and
determining the intensity of bright pixels in the area of interest.

4. The method of clause 3, wherein the object comprises a plurality of the area of interest.

5. The method of clause 1, wherein the determining comprises determining a thickness of the layer.

6. The method of clause 5, wherein the determining comprises determining a wear volume ratio as a function of the thickness of the layer.

7. The method of clause 1, wherein:
the reference model comprises a relation between a thickness of the layer and a transmission value; and
further comprising establishing the reference model comprises determining an extinction factor associated with the coating material.

8. The method of clause 7, wherein:
the object comprises another layer beneath the layer of coating material, and
further comprising establishing the reference model further comprises determining an extinction factor associated with a material of the another layer.

9. The method of clause 8, wherein the establishing the reference model further comprises:
determining transmission spectra for the coating material;
modifying optical density spectra of the coating material based on an optical density of the another layer; and
determining the extinction factor for the coating material based on the modified optical density spectra.

10. The method of clause 8, further comprising:
using a wear resistant layer as the layer, and
using an adhesion layer as the another layer.

11. The method of clause 10, further comprising:
forming the wear resistant layer from Titanium Nitride (TiN), and
forming the adhesion layer from Titanium (Ti).

12. The method of clause 1, further comprising:
determining an intensity of the received light; and
detecting a catastrophic event when the intensity is greater than a threshold.

13. The method of clause 1, further comprising:
integrating an intensity of the received light from 450 nm to 700 nm.

14. The method of clause 1, further comprising forming a plurality of burls on a burl plate on the first side of the object.

15. A system comprising:
an illumination system configured to generate an illumination beam and to direct the illumination beam to irradiate a second side of an object, wherein a first side of the object comprises a layer of a coating material;
a detection system configured to receive scattered light from the first side of the object, wherein the scattered light comprises transmitted light through the object from the second side to the first side; and
processing circuitry configured to:
   generate a signal based on the received light;
   compare the signal to a reference model; and
   determine a quantity of wear of the first side of the object based on the comparing.

16. The system of clause 15, wherein:
the detection system comprises a camera; and
the camera is configured to capture one or more images of the object.

17. The system of clause 16, wherein:
the quantity of wear comprises a wear area ratio, and the wear area ratio is a function of an intensity of bright pixels in the one or more images of the object.

18. The system of clause 15, wherein determining the quantity of wear comprises determining a thickness of the layer of the coating material.

19. The system of clause 15, wherein the reference model comprises a relation between a thickness of the layer and a transmission value.

20. A computer-readable storage medium having instructions stored thereon, execution of which by one or more processors cause the one or more processors to perform operations, the operations comprising:
acquiring a reference model associated with one or more layers of an object;
acquiring one or more images of the object;
comparing a metric associated with the one or more images to the reference model; and
determining a quantity of wear of a top surface of the object based on the comparing.

Although specific reference can be made in this text to the use of the apparatus and/or system according to the invention in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle,” “wafer,” or “die” in this text should be considered as being replaced by the more general terms “mask,” “substrate,” and “target portion,” respectively.

While specific embodiments of the invention have been described above, it will be appreciated that the invention can be practiced otherwise than as described. The description is not intended to limit the invention.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein.

The breadth and scope of the present invention should not be limited by any of the above-described exemplary embodiments, but should be defined only in accordance with the following claims and their equivalents.

1. A method comprising:
irradiating an object with an illumination beam, wherein:
a first side of the object comprises a layer of a coating material, and
the irradiating is from a second side of the object;
receiving, using a detector, scattered light from the first side of the object, wherein the scattered light comprises transmitted light through the object from the second side to the first side;
generating, using the detector, a signal based on the scattered light;
comparing, using a processor, the signal to a reference model; and
determining, using the processor, a quantity of wear of the first side of the object based on the comparing.

2. The method of claim 1, wherein:
the quantity of wear comprises a wear area ratio,
the signal comprises image data of the object,
the object comprises a plurality of the area of interest,
the wear area ratio is a function of an intensity of bright pixels in the image data, and the determining further comprises:
defining an area of interest based on the image data; and
determining the intensity of bright pixels in the area of interest.

3. The method of claim 1, wherein the determining comprises determining a thickness of the layer and determining a wear volume ratio as a function of the thickness of the layer.

4. The method of claim 1, wherein:
the reference model comprises a relation between a thickness of the layer and a transmission value; and
establishing the reference model comprises determining an extinction factor associated with the coating material.

5. The method of claim 4, wherein:
the object comprises another layer beneath the layer of coating material, and
further comprising establishing the reference model further comprises determining an extinction factor associated with a material of the another layer.

6. The method of claim 5, wherein the establishing the reference model further comprises:
determining transmission spectra for the coating material;
modifying optical density spectra of the coating material based on an optical density of the another layer; and
determining the extinction factor for the coating material based on the modified optical density spectra.

7. The method of claim 5, further comprising:
using a wear resistant layer as the layer, and
using an adhesion layer as the another layer.

8. The method of claim 7, further comprising:
forming the wear resistant layer from Titanium Nitride (TiN), and
forming the adhesion layer from Titanium (Ti).

9. The method of claim 1, further comprising:
determining an intensity of the received light;
detecting a catastrophic event when the intensity is greater than a threshold;
integrating an intensity of the received light from 450 nm to 700 nm; and
forming a plurality of burls on a burl plate on the first side of the object.

10. A system comprising:
an illumination system configured to generate an illumination beam and to direct the illumination beam to irradiate a second side of an object, wherein a first side of the object comprises a layer of a coating material;
a detection system configured to receive scattered light from the first side of the object, wherein the scattered light comprises transmitted light through the object from the second side to the first side; and
processing circuitry configured to:
generate a signal based on the received light;
compare the signal to a reference model; and
determine a quantity of wear of the first side of the object based on the comparing.

11. The system of claim 10, wherein:
the detection system comprises a camera; and
the camera is configured to capture one or more images of the object.

12. The system of claim 11, wherein:
the quantity of wear comprises a wear area ratio, and
the wear area ratio is a function of an intensity of bright pixels in the one or more images of the object.

13. The system of claim 10, wherein determining the quantity of wear comprises determining a thickness of the layer of the coating material.

14. The system of claim 10, wherein the reference model comprises a relation between a thickness of the layer and a transmission value.

15. A computer-readable storage medium having instructions stored thereon, execution of which by one or more processors cause the one or more processors to perform operations, the operations comprising:
acquiring a reference model associated with one or more layers of an object;
acquiring one or more images of the object;
comparing a metric associated with the one or more images to the reference model; and
determining a quantity of wear of a top surface of the object based on the comparing.
